(19) United States
(12) Patent Application Publication
(10) Pub. No.: US 2012/0164430 A1
(43) Pub. Date: Jun. 28, 2012

(54) COMPOSITE MATERIAL PART HAVING A CERAMIC MATRIX, AND METHOD FOR MANUFACTURING SAME

(75) Inventors: Jacques Thebault, Bordeaux (FR); Sébastien Bertrand, Moulis-en-Medoc (FR)

(73) Assignee: SNECMA PROPULSION SOLIDE, Le Haillan Cedex (FR)

(21) Appl. No.: 13/393,978

(22) PCT Filed: Jul. 21, 2010
(86) PCT No.: PCT/FR2010/051545

§ 371 Date: Mar. 2, 2012

(30) Foreign Application Priority Data
Sep. 28, 2009 (FR) 0956694

(51) Int. Cl. B32B 18/00; B05D 5/00; B05D 1/36; C23C 16/44

(52) U.S. Cl. 428/293.4; 427/255.7; 427/258

(57) ABSTRACT

In a composite material part having a ceramic matrix and including a fibrous reinforcement which is densified by a matrix consisting of a plurality of ceramic layers having a crack-diverting matrix interphase positioned between two adjacent ceramic matrix layers, the interphase includes a first phase made of a material capable of promoting the diversion of a crack reaching the interphase according to a first propagation mode in the transverse direction through one of the two ceramic matrix layers adjacent to the interphase, such that the propagation of the crack continues according to a second propagation mode along the interphase, and a second phase consisting of discrete contact pads that are distributed within the interphase and capable of promoting the diversion of the crack that propagates along the interphase according to the second propagation mode, such that the propagation of the crack is diverted and continues according to the first propagation mode through the other ceramic matrix layer that is adjacent to the interphase.

### BACKGROUND OF THE INVENTION

The invention relates to composite material parts having a ceramic matrix, in particular, but not exclusively, parts for aeronautic engines or rocket engines.

Ceramic matrix composites (CMC) are made up of a fibrous reinforcement, in carbon or ceramic fibers, densified by a ceramic matrix. Their mechanical properties and temperature resistance make them suitable for use for structural parts exposed to high temperatures during use.

However, CMCs are subject to cracking under the effect of thermomechanical strains, often as of their production. In order to prevent the fibers of the fibrous reinforcement from breaking due to the cracks spreading through the matrix, and to prevent the rapid deterioration of the mechanical properties that would result therefrom, is well known to position an embrittlement relief interphase between the fibers and the matrix. Such an interphase is typically made from a material with a lamellar structure or texture which, when the crack reaches the interface, is capable of dissipating the cracking energy through a localized debonding so that the crack is diverted within the interphase. Component materials of an embrittlement relief interphase are in particular pyrolytic carbon PyC and boron nitride BN, which have a lamellar structure.

Reference may be made to documents U.S. Pat. No. 4,752,503 and U.S. Pat. No. 5,026,604. Other materials can be used, for example such as boron-doped carbon BC and titanium silicocarbide Ti₃SiC₂.

In the case of use in a corrosive environment (oxidizing or humid medium), it is desirable to avoid easy access via cracking to the fibers of the reinforcement or to the fiber/matrix interphase when the fibers or interphase are made from a material, such as carbon, that is sensitive to such a corrosive environment.

To that end, it has been proposed to make the matrix at least partially through a self-healing ceramic phase made from a material capable, in the presence of oxygen, of forming a glass which, by passing into a fluid state at usage temperatures of the CMC material, can cause clogging or healing of cracks. A healing ceramic phase for example comprises the elements Si, B and C able to form a borosilicate glass. Reference may for example be made to document U.S. Pat. No. 5,965,266.

It has also been proposed to dissipate the cracking energy within the matrix, before the cracks reach the fiber/matrix interphase, by forming the matrix from several ceramic layers while positioning a crack-diverting interphase between two adjacent matrix layers, the matrix phases also being able to be self-healing. Reference may for example be made to documents U.S. Pat. No. 5,074,039 and U.S. Pat. No. 6,068,930.

However, the effectiveness of self-healing matrix phases is limited to a particular temperature range. The introduction of crack-deviating interfaces between matrix phases as proposed in the state of the art also has a limited effectiveness over time, the debondings created by the spread of the cracks in the interfaces being able to lead to peeling of the CMC material over time.

### SUBJECT MATTER AND BRIEF DESCRIPTION OF THE INVENTION

The invention therefore aims to provide a CMC part having a longer lifespan for use at a high temperature, up to at least 1000° C., and even up to at least 1200° C., in a corrosive environment.

This aim is achieved owing to a CMC part comprising a fibrous reinforcement which is densified by a matrix consisting of a plurality of ceramic layers having a crack-diverting matrix interphase positioned between two adjacent ceramic matrix layers, wherein the interphase includes:

a first phase made of a material capable of promoting the diversion of a crack reaching the interphase according to a first propagation mode in the transverse direction through one of the two ceramic matrix layers adjacent to the interphase, such that the propagation of the crack continues according to a second propagation mode along the interphase, and

a second phase consisting of discrete contact pads that are distributed within the interphase and capable of promoting the diversion of the crack that propagates along the interphase according to the second propagation mode, such that the propagation of the crack is diverted and continues according to the first propagation mode through the other ceramic matrix layer that is adjacent to the interphase.

In a CMC material comprising several matrix layers with an interphase positioned between two adjacent matrix layers, here we distinguish between a first crack propagation mode (or mode I) in the transverse direction in the matrix layers, and a second longitudinal propagation mode (mode II) along an interphase, within the latter or at an interface between the interphase and an adjacent matrix layer.

The invention is remarkable for the capacity of the interphase to ensure deviate a crack reaching the interphase from an adjacent matrix phase by going from the first to the second propagation mode, followed by a redirection of the crack toward the other adjacent matrix phase by going from the second propagation mode back to the first propagation mode. In this way, the risk of peeling is reduced by limiting the extent of the debonding within the interphase layer and the resistance to the corrosive environment is extended by imposing a twisting journey on the cracks that extends the path through which the surrounding medium may potentially access the fibers of the fibrous reinforcement or a fiber/matrix interphase.

In one embodiment, the discrete contact pads making up the second phase perform localized bridging between the two ceramic matrix layers. The discrete contact pads then form a second binding phase by performing a mechanical connecting function between the matrix layers adjacent to the interphase. The discrete contact pads can be made from ceramic, for example silicon carbide SiC, another structural carbide, or a structural nitride, and can be formed integrally with one of the two adjacent ceramic matrix layers.

Preferably, the discrete contact pads occupy a surface fraction of the interphase of between 20% and 80%.

The material of the first phase of the interphase can be selected in the group made up of pyrolytic carbon PyC, boron nitride BN, boron-doped carbon BC, and a MAX phase, in particular titanium silicocarbide Ti₃SiC₂.

Preferably, the interphase has a thickness of between 0.01 micron and 2 microns.

According to another aspect, the invention also aims to provide a method making it possible to produce a CMC part as defined above.

This aim is achieved owing to a method comprising the production of a fibrous preform and the densification of the fibrous preform by a matrix made up of several ceramic layers having a crack-deviating interphase placed between two adjacent ceramic matrix layers, in which the interphase is made with:

a first phase made of a material capable of promoting the diversion of a crack reaching the interphase according to a first propagation mode in the transverse direction through one of the two ceramic matrix layers adjacent to the interphase, such that the propagation of the crack continues according to a second propagation mode along the interphase, and

a second phase consisting of discrete contact pads that are distributed within the interphase and capable of promoting the diversion of the crack that propagates along the interphase according to the second propagation mode, such that the propagation of the crack is diverted and continues according to the first propagation mode through the other ceramic matrix layer that is adjacent to the interphase.

According to a first particular embodiment of the method, the interphase is made by co-deposition of the first phase and the second phase by chemical vapor infiltration.

According to a second particular embodiment of the method, the interphase is made by chemical vapor infiltration deposition on a ceramic matrix layer of a continuous layer of the material of the first phase, localized elimination of the material of the deposited layer to form a discontinuous layer, and filling in the spaces thus formed by depositing a material making up the second phase. The filling in of the spaces can be done by depositing a ceramic material during the formation of a subsequent ceramic matrix layer.

According to a third particular embodiment of the method, the interphase is made by discontinuous deposition on a ceramic matrix layer of a component material or precursor of the material of the first phase to form patches spaced apart from one another and filling in spaces between the patches by depositing a material making up the second phase. The filling in of the spaces can be done by ceramic material deposition during the formation of a subsequent ceramic matrix layer.

In this third embodiment of the method, it is possible to perform the discontinuous deposition by suspending, in a liquid carrier, particles of the component material or precursor of the material of the first phase; impregnating the ceramic matrix layer with the suspension; and eliminating the liquid binder to obtain particles dispersed on the surface of the ceramic matrix layer.

When the discontinuous deposition is formed by a precursor material of the material of the first phase, the transformation of the precursor material may occur by chemical reaction with a gas phase, during the formation of a subsequent ceramic matrix layer.

In a fourth embodiment of the method, the interphase is made through the formation, on a ceramic matrix layer, of nodules forming the discrete contact pads of the second phase, and the deposition of a layer of a material making up the first phase.

### BRIEF DESCRIPTION OF THE DRAWINGS

The invention will be better understood upon reading the following description, provided for information but non-limitingly in reference to the appended drawings, in which:

FIG. 1 very diagrammatically shows the propagation of a crack in the matrix of the CMC material having several ceramic matrix phases separated by embrittlement relief interphases according to the prior art;

FIG. 2 very diagrammatically illustrates the propagation of a crack in the matrix of a CMC material according to the invention having several ceramic matrix phases separated by interphases;

FIG. 3 very diagrammatically illustrates an example of an interphase according to the invention;

FIG. 4A very diagrammatically illustrates another example of an interphase according to the invention, and FIG. 4B shows the propagation of a crack with redirection in such an interphase;

FIGS. 5A to 5C show the successive steps of a method for making an interphase like that of FIG. 4A;

FIGS. 6A and 6B shows successive steps of another method of making an interphase like that of FIG. 4A;

FIGS. 7A to 7C show the successive steps of still another method of making an interphase according to the invention;

FIG. 8 is a scanning electron microscope view of a C+SiC co-deposit;

FIGS. 9 to 11 are scanning electron microscope views showing crack propagation modes;

FIG. 12 is a scanning electron microscope view showing nodules formed on a surface of a ceramic phase; and

FIG. 13 is a scanning electron microscope view showing an interphase according to the invention between two ceramic layers.

### DETAILED DESCRIPTION OF THE INVENTION

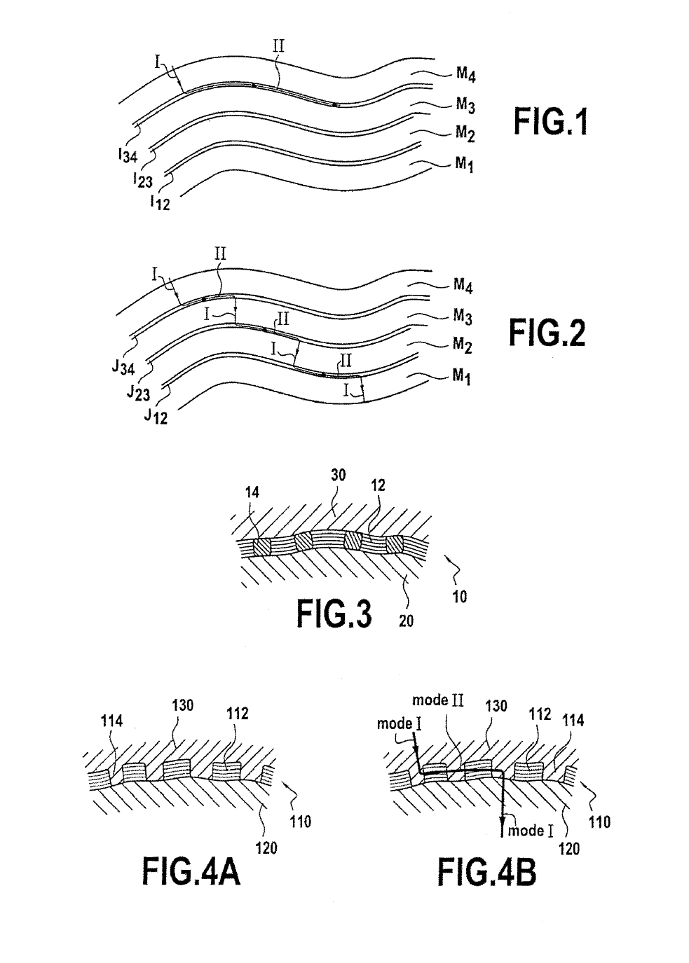

FIG. 1 very diagrammatically illustrates part of a known CMC material comprising several ceramic matrix layers or phases M₁, M₂, M₃, M₄ with an embrittlement relief interphase I₁₂, I₂₃, I₃₄ positioned between two adjacent matrix layers. The interphases are made from a crack-deviating material, for example PyC, BN, BC or Ti₃SiC₂, so that a crack F reaching an interphase I₁₂ by spreading transversely in an adjacent matrix layer M₄ (crack propagation mode I) is deviated to continue its propagation along the interphase I₃₄ through debonding within the latter or at an interface between the interphase I₃₄ and an adjacent matrix layer M₃ or M₄ (crack propagation mode II).

In this way, the propagation of the crack through the entire matrix until it reaches the fibers of the CMC material is avoided or delayed. However, the debonding corresponding to mode II propagation of course causes a risk of peeling of the CMC material.

FIG. 2 very diagrammatically illustrates part of a CMC material according to the invention comprising several ceramic matrix layers or phases M₁, M₂, M₃, M₄ with a mixed interphase J₁₂, J₂₃, J₃₄ positioned between two adjacent matrix layers. Each mixed interphase is formed by the juxtaposition of two phases:
a first debonding phase made from a crack-deviating material capable of promoting the deviation of a crack reaching the interphase in mode I to mode II, and
a second phase made up of discrete contact pads (not shown in FIG. 2) capable of promoting the redirection of a crack propagating in mode II along the interphase into mode I.

In this way, a crack F reaching an interphase propagating in mode I through a ceramic matrix layer adjacent to the interphase is deviated to propagate in mode II along the interphase over a limited distance before being deviated again to continue its propagation in mode I through the other ceramic matrix layer adjacent to the interphase.

In this way, the risk of peeling is eliminated or at least greatly reduced. Furthermore, the winding path of the cracks makes it more difficult for corrosive species to reach the core of the material.

The mixed interphase can have a relatively small thickness, for example between 0.01 micron and 2 microns.

A mixed interphase offering a dual deviation capacity from mode I into mode II and redirection from mode II back to mode I can be made in different ways.

Producing a CMC material part with several matrix layers separated by interphases, in a known manner, comprises the following steps:

(a) making a fibrous preform having a shape corresponding to that of the part to be made, the preform being made from carbon or ceramic fibers,

(b) forming a fiber/matrix embrittlement relief interphase layer on the fibers, said interphase layer possibly being able to be formed before producing the fibrous preform,

(c) forming a ceramic matrix layer,

(d) forming an interphase on the ceramic matrix layer,

(e) forming a ceramic matrix layer, and

(f) possibly repeating steps (c) to (e) one or more times.

The fibrous preform can for example be obtained by shaping fibrous textures possibly in superimposed plies, such as sheets of threads, traditional two-dimensional (2D) fabrics or three-dimensional (3D) or multilayer fabrics.

In the case of a part to be made with a relatively complex shape, the fibrous preform may be consolidated to freeze it in the desired shape using a liquid method by impregnation using a consolidation composition containing a carbon or ceramic precursor resin, then curing and pyrolysis of the resin. A liquid consolidation process for preforms more particularly intended to produce CMC parts is described in the French patent application filed under no. 0854937 by the applicant.

The fiber/matrix interphase layer, the interphases between ceramic matrix layers, as well as the ceramic matrix layers can be made by chemical vapor infiltration (CVI). To that end, the fibrous preform, possibly consolidated, is placed in an oven, and a reactive gaseous phase containing one or more precursors of the material to be deposited is introduced into the oven. The pressure and temperature conditions in particular are chosen to allow the gaseous phase to diffuse within the fibrous preform and form a desired deposit therein through decomposition of a component of the gaseous phase or through reaction between several components. The composition of the reactive gaseous phase and, if applicable, the conditions for the CVI process (temperature, pressure, precursor level in the gaseous phase, residence time of the gaseous phase in the oven, etc.) are then modified during the transition of the deposition of a matrix layer in a given material to an interphase layer in another material (or vice versa). Reference may be made to the documents cited at the beginning of the description regarding the production of embrittlement relief interphases or ceramic matrix layers by CVI.

As indicated below, the interphase may be at least partially made using a method other than a CVI process.

FIG. 3 very diagrammatically illustrates a first embodiment of a mixed interphase 10 according to the invention between two ceramic matrix layers 20 and 30.

The interphase 10 comprises a first debonding phase 12 in a material capable of promoting the diversion of a crack toward mode II by debonding, and a second phase 14 made up of grains or discrete contact pads capable of promoting the redirection of the crack from mode II to mode I, the grains or contact pads of the phase 14 producing a bonding by localized bridging between the ceramic matrix layers 20 and 30.

The debonding phase 12 can for example be made from pyrolytic carbon PyC, boron nitride BN, boron-doped carbon BC (with between 5% at. and 20% at. B, the rest being C) or a MAX phase such as Ti₃SiC₂. The grains or contact pads forming the bonding phase 14 can be made from ceramic, for example silicon carbide SiC, another structural carbide or a structural nitride.

The interphase 10 can be obtained by co-deposition of phases 11 and 12 on the ceramic matrix layer 20. For example, a CVI co-deposition of a PyC phase 12 and a SiC phase 14 can be done by using a reactive gaseous phase made up of methyltrichlorosilane (MTS) and hydrogen H₂ with a very low ratio α between H₂ rate and MTS rate, for example α<1.

After formation of the interphase 10, the following ceramic layer 30 is formed. The matrix layers and the interphases are thus successively produced.

FIG. 4 very diagrammatically illustrates another embodiment of a mixed interphase 110 according to the invention between two ceramic matrix layers 120 and 130.

The interphase comprises a first debonding phase 112 made from a material capable of diverting a crack toward mode II, and a second bonding phase 114 made up of discrete contact pads that produce a bonding by localized bridging between the layers of ceramic material while being formed with one of the matrix layers.

The first separating phase 112 can for example be made from PyC, BN, BC, or a MAX phase such as Ti₃SiC₂.

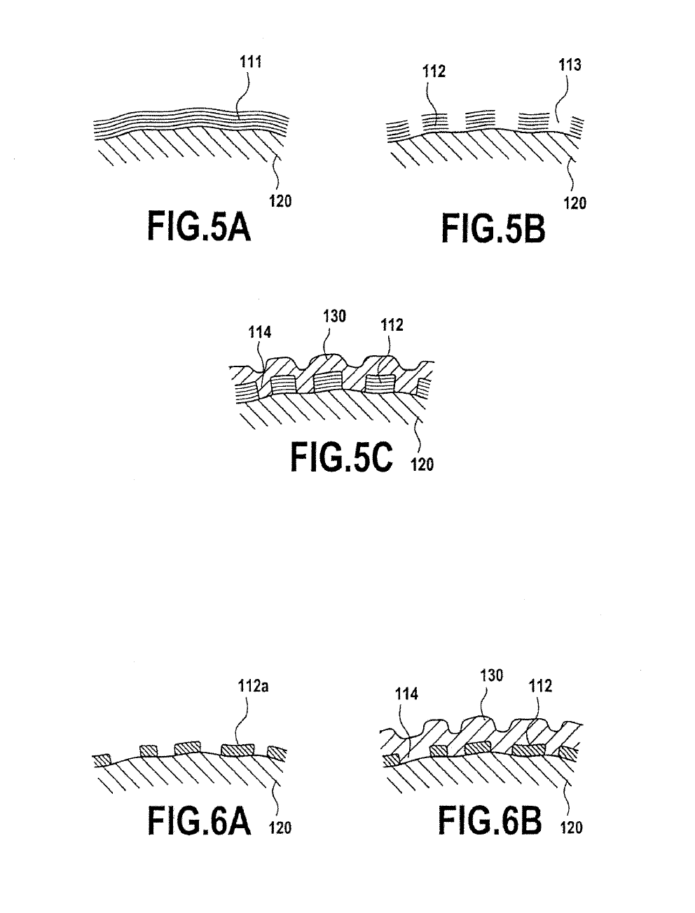

One method of forming the interphase 110 is shown by FIGS. 5A to 5C.

After producing the matrix layer 120, a continuous layer 111 of debonding phase material is formed by CVI on the matrix layer 120 (FIG. 5A).

The layer 111 is locally eliminated to allow patches 112 separated from one another to remain (FIG. 5B). The local elimination of the layer 111 can be done by chemical or physical etching.

Then, the ceramic material of the layer 130 is deposited by CVI, in particular occupying the spaces between the patches 112 to form the contact pads 114.

Another method of forming the interphase 110 is shown by FIGS. 6A and 6B.

After producing the ceramic matrix layer 120, patches 112a of a debonding phase material or a precursor material of the debonding phase material are formed on the layer 120 (FIG. 6A). The patches 112a are separated from one another.

To form the patches 112a, the following procedure may be used:
preparation of a suspension in a liquid carrier of particles of the material of the debonding phase or of a precursor material of the material of the debonding phase,
impregnation of the matrix layer 120 by the suspension, and
elimination of the solid carrier to leave isolated particles dispersed on the surface of the matrix layer 120, while being anchored in the surface porosity of the layer 120, which always has a residual porosity, the particles having a size chosen not to exceed the thickness of the interphase to be produced.

The patches 112a can form the separating phase 112 either directly, or through chemical reaction with a gaseous phase brought in before the deposition of the following matrix layer 130 or by chemical reaction during the deposition of that matrix layer.

In this way, it is possible to form the patches 112a using titanium as the precursor that yields contact pads 112 made from Ti₃SiC₂ by reaction with an SiC gaseous precursor phase used to form the matrix layer 130.

The ceramic material of the matrix layer 130 is deposited by CVI, in particular occupying the spaces between the patches 112a to form the contact pads 114 (FIG. 6B).

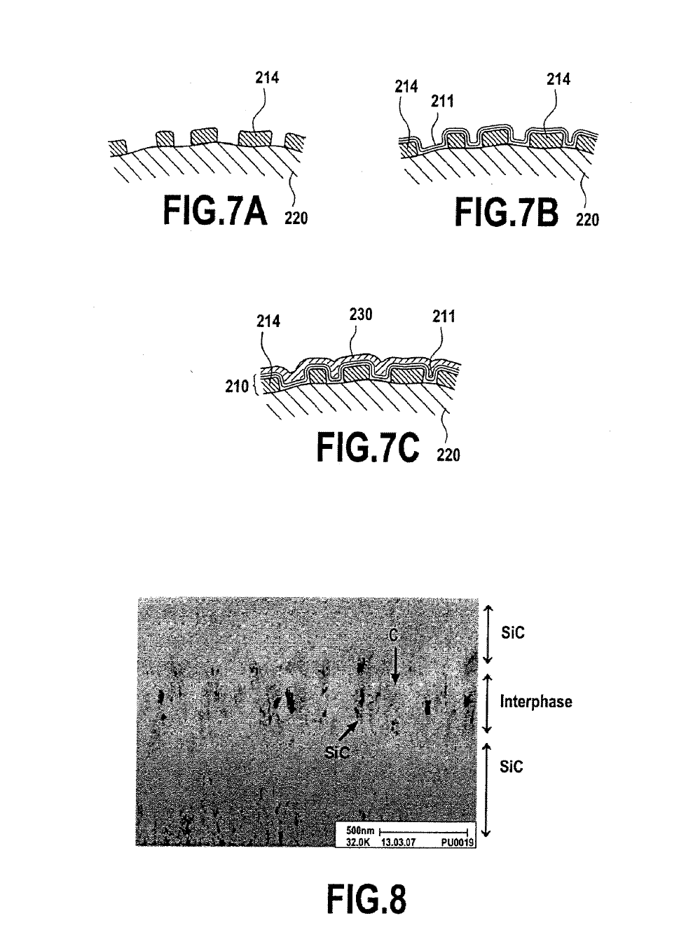

FIGS. 7A to 7C very diagrammatically illustrate still another method for producing a mixed interphase according to the invention.

Nodules 214 intended to form the discrete contact pads of the second phase of the interphase to be produced are deposited on a ceramic matrix layer 220 (FIG. 7A).

The nodules 214 can be obtained by chemical vapor deposition (CVD) by choosing deposition conditions yielding a discontinuous deposition formed by discrete nodules and not a continuous layer. In this way, for example, SiC or SiC+Si nodules can be obtained by using a gaseous phase comprising a mixture of MTS, H₂, and hydrogen chloride HCl with a ratio a between the H₂ and MTS rates and a ratio δ between the HCl and MTS rates selected to that end, α preferably being comprised between 5 and 25, and δ preferably being comprised between 0.05 and 2.

A continuous layer 211 of debonding phase is then formed by CVI on the matrix phase 220 and the nodules 214 (FIG. 7B). The debonding phase can for example be made from PyC, BN, BC, or MAX phase such as Ti₃SiC₂. One thus obtains the matrix interphase 210 comprising the nodules 214 and the layer 211.

The following matrix layer 230 is then formed on the debonding phase 211.

The matrix phases 220 and 230 advantageously being formed by CVI, the production of the nodules 214 by CVD makes it possible to link the steps for forming the matrix phases and the interphase in an oven by modifying the composition of the reactive gaseous phase.

The deposition on the matrix layer 220 of solid particles forming the second phase of the interphase could, however, be done by forming a suspension of small solid ceramic particles in a liquid carrier, for example SiC, impregnating the matrix layer 220 with the suspension, and eliminating the liquid carrier to leave the ceramic particles dispersed on the surface of the matrix layer and anchored in the surface porosity.

Examples of the production of interphases will now be described. In these examples, the interphases have been produced on monolithic substrates and not on composite substrates with fibrous reinforcements, the aim being to show the feasibility and the effects of the interphases.

### EXAMPLE 1

Produced on a silicon substrate was an assembly: SiC/SiC+PyC interphase/SiC/SiC+PyC interphase/SiC, in which:
the SiC layers are stoichiometric layers obtained by CVI in a well-known manner from a MTS+H₂ gaseous phase at a temperature of approximately 1000° C. and under a pressure of approximately 5 kPa, the ratio α between the H₂ rate and the MTS rate being approximately 6,
the SiC+PyC interphases are obtained by CVI from a MTS+H₂ gaseous phase yielding a first debonding phase PyC with a lamellar structure and a second phase made up of PyC crystallites, the conditions being the same as those leading to the obtainment of stoichiometric SiC with the exception of the ratio α, which is chosen to be less than 1.

By choosing, for the formation of each interphase, a ratio α equal to approximately 0.1 (complete) and a duration of 1.5 min, an interphase was obtained with a thickness approximately equal to 30 nm containing 80% at. of PyC, the rest being formed by SiC crystallites.

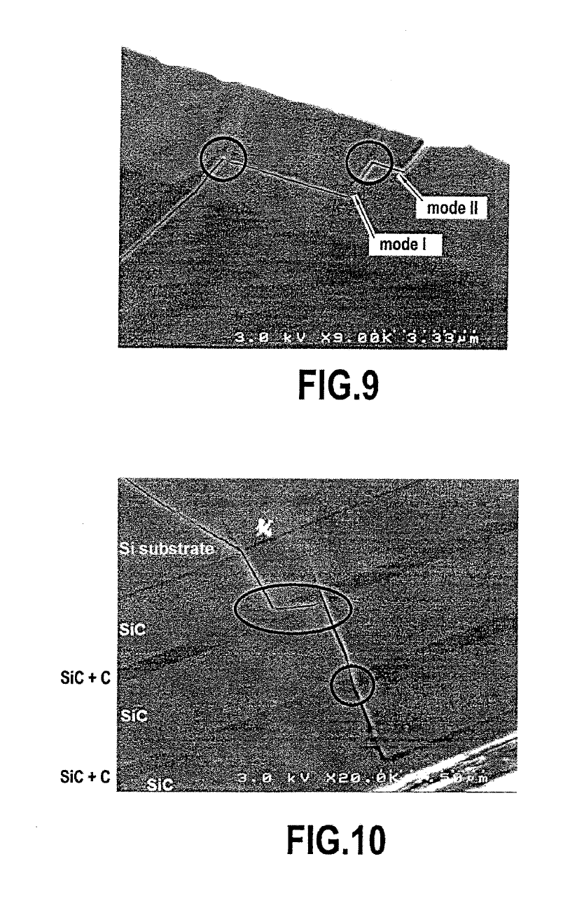

FIG. 8 shows an obtained interphase, while FIG. 9 shows the path of a crack caused by indentation under a load. In FIG. 9, the circles indicate crack redirection zones (transitions from mode II to mode I).

### EXAMPLE 2

The same procedure was used as in example 1, but during the production of each interphase, with a ratio α approximately equal to 0.25 and a duration of 5 min., SiC+PyC interphases were obtained with a thickness approximately equal to 0.3 micron containing 70% at. of PyC, the rest being formed by SiC crystallites.

FIG. 10 shows the path of a crack caused by indentation under a load. One can see an absence of transition from mode I to mode II in the second interphase, such a transition with redirection into mode I occurring in the first interphase.

### EXAMPLE 3

The same procedure was used as in example 1, but during the production of each interphase, with a ratio α approximately equal to 0.5 and a duration of 5 min., SiC+PyC interphases were obtained with a thickness approximately equal to 0.2 micron containing 60% at. of PyC, the rest being formed by SiC crystallites.

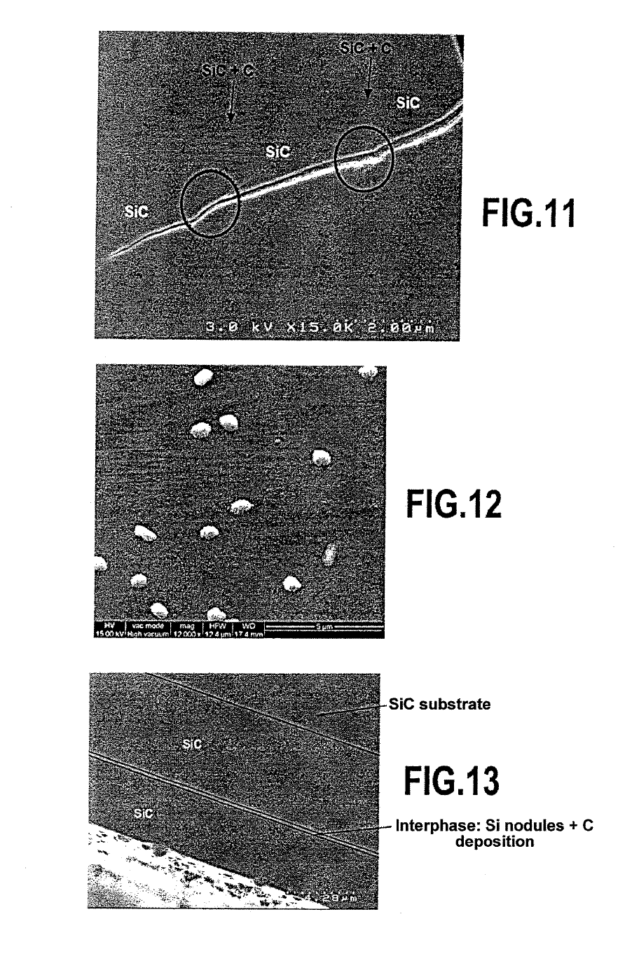

FIG. 11 shows the path of a crack caused by indentation under a load. One can see an absence of transition from mode I to mode II in both interphases, reflecting the insufficient presence of a debonding phase.

### EXAMPLE 4

SiC+Si (non-stoichiometric SiC highly enriched with Si) nodules were formed by CVD on a SiC substrate using a gaseous MTS+H₂+HCl phase, at a temperature of approximately 1000° C., under a pressure of approximately 5 kPa and with α and δ rate ratios equal to approximately 8 and approximately 0.5, respectively, the deposition time being approximately 30 min.

FIG. 12 shows the obtained SiC+Si nodules. They have an average diameter of approximately 300 nm and an average height of approximately 100 nm and the mean distance between nodules is approximately 5 microns.

### EXAMPLE 5

Produced on a silicon substrate was an assembly: SiC/(SiC+Si)+PyC interphase/SiC, in which:
the SiC layers are stoichiometric SiC layers obtained by CVI as in example 1,
the (SiC+Si)+PyC interphase is obtained by CVD deposition of discrete SiC+Si nodules, then CVI deposition of a continuous PyC layer.

The CVD deposition of the SiC+Si nodules (non-stoichiometric SiC highly enriched with Si) was obtained by using a gaseous MTS+H₂+HCl phase, at a temperature of approximately 1000° C., under a pressure of approximately 5 kPa and with α and δ rate ratios equal to approximately and approximately 0.5, respectively, the deposition time being approximately 30 min.

The deposition of the continuous PyC layer was obtained by using a gaseous phase containing propane, at a temperature of about 1000° C., under a pressure of about 5 kPa, the deposition time being about 2.5 min.

FIG. 13 shows the obtained interphase with a mean thickness approximately equal to 50 nm.

1. A composite material part having a ceramic matrix and comprising a fibrous reinforcement which is densified by a matrix consisting of a plurality of ceramic layers having a crack-diverting matrix interphase positioned between two adjacent ceramic matrix layers, wherein the interphase includes:
a first phase made of a material capable of promoting the diversion of a crack reaching the interphase according to a first propagation mode in the transverse direction through one of the two ceramic matrix layers adjacent to the interphase, such that the propagation of the crack continues according to a second propagation mode along the interphase, and
a second phase consisting of discrete contact pads that are distributed within the interphase and capable of promoting the diversion of the crack that propagates along the interphase according to the second propagation mode, such that the propagation of the crack is diverted and continues according to the first propagation mode through the other ceramic matrix layer that is adjacent to the interphase.

2. A part according to claim 1, wherein the discrete contact pads making up the second phase perform localized bridging between the two ceramic matrix layers.

3. A part according to claim 2, wherein the discrete contact pads are made from ceramic.

4. A part according to claim 3, wherein the discrete contact pads are formed integrally with one of the two adjacent ceramic matrix layers.

5. A part according to claim 1, wherein the discrete contact pads occupy a surface fraction of the interphase of between 20% and 80%.

6. A part according to claim 1, wherein the material of the first phase of the interphase is selected in the group made up of pyrolytic carbon PyC, boron nitride BN, boron-doped carbon BC, and a MAX phase, in particular titanium silicocarbide Ti₃SiC₂.

7. A part according to claim 1, wherein the interphase has a thickness of between 0.01 micron and 2 microns.

8. A method for producing a composite material part having a ceramic matrix, comprising the production of a fibrous preform and the densification of the fibrous preform by a matrix made up of several ceramic layers having a crack-deviating interphase placed between two adjacent ceramic matrix layers, in which the interphase is made with:
a first phase made of a material capable of promoting the diversion of a crack reaching the interphase according to a first propagation mode in the transverse direction through one of the two ceramic matrix layers adjacent to the interphase, such that the propagation of the crack continues according to a second propagation mode along the interphase, and
a second phase consisting of discrete contact pads that are distributed within the interphase and capable of promoting the diversion of the crack that propagates along the interphase according to the second propagation mode, such that the propagation of the crack is diverted and continues according to the first propagation mode through the other ceramic matrix layer that is adjacent to the interphase.

9. A method according to claim 8, wherein the interphase is made by co-deposition of the first phase and the second phase by chemical vapor infiltration.

10. A method according to claim 8, wherein the interphase is made by chemical vapor infiltration deposition on a ceramic matrix layer of a continuous layer of the material of the first phase, localized elimination of the material of the deposited layer to form a discontinuous layer, and filling in the spaces thus formed by depositing a material making up the second phase.

11. A method according to claim 8, wherein the interphase is made by discontinuous deposition on a ceramic matrix layer of a component material or precursor of the material of the first phase to form patches spaced apart from one another and filling in spaces between the patches by depositing a material making up the second phase.

12. A method according to claim 11, wherein the discontinuous deposition is carried out by suspending, in a liquid carrier, particles of the component material or precursor of the material of the first phase; impregnating the ceramic matrix layer with the suspension; and eliminating the liquid carrier to obtain particles dispersed on the surface of the ceramic matrix layer.

13. A method according to claim 10, wherein the discontinuous deposition is formed by a precursor material of the material of the first phase, and the transformation of the precursor material is done by chemical reaction with a gas phase, during the formation of a subsequent ceramic matrix layer.

14. A method according to claim 10, wherein the filling in of the spaces is done by ceramic material deposition during the formation of a subsequent ceramic matrix layer.

15. A method according to claim 8, wherein the interphase is made through the formation, on a ceramic matrix layer, of nodules forming the discrete contact pads of the second phase, and the deposition of a layer of a material making up the first phase.
